(19) United States
(12) Patent Application Publication
(10) Pub. No.: US 2006/0079018 A1
(43) Pub. Date: Apr. 13, 2006

(54) Method for producing an optical or electronic module provided with a plastic package

(75) Inventors: Hans Hurt, Regensburg (DE); Martin Weigert, Hardt (DE)

Correspondence Address: BEVER HOFFMAN & HARMS, LLP;TRI-VALLEY OFFICE, 1432 CONCANNON BLVD., BLDG. G, LIVERMORE, CA, 94550, US

(73) Assignee: Infineon Technologies Fiber Optics GmbH, Berlin (DE)

(21) Appl. No.: 11/246,025

(22) Filed: Oct. 7, 2005

(30) Foreign Application Priority Data
Oct. 8, 2004 (EP) 04090388.2

(51) Int. Cl. H01L 21/50

(52) U.S. Cl. 438/64; 438/116; 438/69

(57) ABSTRACT

A method for producing an optical or electronic module provided with a plastic package in which at least one optical or electronic component having an operative region is encapsulated with at least one polymer compound to form the plastic package. Portions of the polymer compound are then removed by a device, such as a laser, in such a way that an opening is defined in the polymer compound between the operative region of the component and the outer side of the plastic package. A functional structure is then introduced into the remaining polymer compound by the device.

### FIELD OF THE INVENTION

The invention relates to a method for producing an optical or electronic module provided with a plastic package, in which, after the encapsulation of the module components with a polymer compound, a component which is in operative connection with the surroundings is partially exposed again in a subsequent method step.

### BACKGROUND OF THE INVENTION

It is known to embed optoelectronic modules with a transparent embedding material. For example, DE 199 09 242 A1 discloses an optoelectronic module in the case of which a leadframe with an optoelectronic transducer is positioned in a module package and embedded with a transparent, moldable polymer material. Light is coupled in or out by means of an optical fiber, which is coupled to a connecting piece of the module package. On the leadframe there is also the driver device or receiving device for the optoelectronic transducer.

However, the use of embedding materials that are transparent for the respective range of wavelengths has disadvantages to the extent that transparent embedding materials generally have a high coefficient of thermal expansion and accordingly, when there are great temperature fluctuations, stresses which can damage the sensitive bonding wire connections in particular occur in the package.

It is therefore advantageous in principle to use for embedding or press-molding the components of a module non-transparent polymer materials provided with fillers which produce a favorable coefficient of thermal expansion of the polymer material. A disadvantage of the use of such polymers as an embedding material is that an optical path cannot be created within the embedding material.

A further problem is that of coupling to a module embedded with an embedding compound further components such as an optical fiber or an optical element in such a way that there is good coupling with the optoelectronic transducer.

Comparable problems may also arise in the case of purely electronic modules provided with a plastic package whenever it is required to bring a component of the module into operative connection with the surroundings.

### SUMMARY OF THE INVENTION

The present invention provides a method for producing an optical or electronic module provided with a plastic package which makes it possible to bring an embedded component of the module into operative connection with the surroundings and couple it with further components in an effective way.

It is envisaged to expose the component again after the encapsulation with a polymer material by means of a device for the partial removal of the polymer material, i.e., to remove the polymer material covering the component at least partially again in order that said component can enter into operative connection with the surroundings. The solution according to the invention is distinguished by the fact that the device for the partial removal of the polymer compound at the same time introduces a functional structure into the remaining polymer compound. Such a functional structure makes possible in particular a passive adjustment and/or attachment of a component to be coupled with respect to the module and the optical or electrical component. The component to be coupled is, for example, an optical fiber or optical plug or an optical element such as a window, a deflecting device, a prism, a filter, a lens and the like. However, the functional structure does not necessarily have to relate to an element to be coupled, but may also concern only functionalities of the module itself, such as for instance the provision of equalizing regions for receiving polymer material or the provision of ventilating ducts.

It is pointed out that an encapsulation of the module does not necessarily take place with only one polymer compound. It is also possible to use a number of polymer compounds, which possibly have differing transparency. For example, it may be provided that the component to be exposed is initially encapsulated with a transparent polymer compound. This is followed by encapsulation with a non-transparent polymer compound. In a subsequent partial removal of the polymer compound, it is then adequate that the non-transparent polymer compound is removed. Accordingly, depending on the configuration, it is adequate that the polymer compound between the operative region of the component and the outer side of the plastic package is not removed completely, but possibly only partially. If a non-transparent polymer compound is exclusively used for the encapsulation, however, the operative region of the component is exposed completely.

An operative region of the optical or electrical component refers to any region that permits an operative connection of the component to the surroundings. For example, it is the photosensitive region of a photodiode, the sensor region of a pressure sensor or a temperature sensor, the light-emitting region of a semiconductor laser or an LED or the area of a lens, a mirror or prism that is facing the outer side of the module.

In a preferred configuration, it is provided that, before or after the partial removal of the polymer compound, the position of the component is recorded by direct or indirect measurement, the functional structure being inscribed in the polymer compound in a defined position in relation to the recorded position of the component. This makes it possible to align the functional structure exactly with the component, so that a further element, such as an optical fiber, can be passively adjusted with respect to the component by means of the functional structure.

A direct measurement of the position of the component means that its position with respect to an external system of coordinates lying outside the module is directly recorded by measurement. In the case of an indirect measurement of the position, on the other hand, the module itself or an element of the module such as a leadframe represents the system of coordinates and the reference system for the positional determination of the component. The relative position is recorded and stored for example when the component is attached to the leadframe, so that the information is available when a functional structure is inscribed in the package. An example of indirect measurement of the position of the component is the registration of the position by means of an image recognition system, for example using a camera system and an assigned computer. The information obtained in this way on the position of the component serves in this case as a reference for the provision of the functional structures. A particularly exact alignment of the functional structures with respect to the component is in this case possible whenever the position of the component is only determined exactly after it has been exposed. Possible inaccuracies during the opening of the module (i.e. the component does not lie centrally in the opening—in the way desired) can then still be corrected by aligning the functional structures with the actual position of the component.

Further possibilities for recording the position of the component are measurement by means of an ultrasonic measuring device or an X-ray measuring device.

It is pointed out that, as an alternative, the functional structure may also be inscribed in the polymer compound in a defined position in relation to the opening which is created when the polymer compound in the plastic package is partially removed. Here, not the component but the opening serves as a reference for the functional structure. This is appropriate in particular whenever the functionality of the functional structure is in connection with the opening itself. The information on the position of the opening is of course available to the device for the partial removal of the polymer material, so that such an alignment of the functional structure can be easily realized.

In a preferred configuration, as already mentioned, the functional structure comprises at least one adjustment structure, which permits a passive adjustment of an element to be coupled to the module with respect to the component. The adjustment structure comprises, for example, at least one adjustment mark, which is inscribed in the surface of the plastic package and permits a passive adjustment of an element to be coupled.

Furthermore, it may be provided that the adjustment structure serves not only for adjustment but also directly for attachment of the element to be coupled. In this case, the adjustment structure comprises attachment structures, which permit attachment of an element to be coupled in a defined position on the plastic package. Such an attachment structure is, for example, a bore or a blind hole which is inscribed in the plastic package. The attachment structure may also be a package connecting piece, which is inscribed in the plastic package and serves for the direct coupling of an optical plug. In particular, it is the coupling connecting piece of a CAI (Cavity as Interface) package.

In a preferred configuration of the invention, it is provided that the opening which is created when the polymer compound in the plastic package is partially removed is filled with a transparent embedding material after the exposure of the component. For this purpose, silicone may be used for example as the embedding compound. However, the filling of the opening with an embedding material entails the risk of the formation of air bubbles, and with it a deterioration of the optical coupling with the component. In order to avoid this, in a further aspect of the invention it is provided that the functional structure has at least one ventilating duct, which extends from the surface of the plastic package into the interior of the plastic package adjacent the opening in the plastic package. Through this ventilating duct, air bubbles created during filling can escape in an improved way.

Furthermore, it may be provided that a shallow recess, which forms an equalizing reservoir for the transparent embedding material with which the opening is filled, is formed laterally of the opening in the surface of the plastic package as a functional structure or part of the functional structure.

The optical or electronic component is preferably arranged on a carrier before the encapsulation. The carrier of the module preferably takes the form of a leadframe, also referred to as a metal carrier or a stamped grid. The leadframe preferably has in this case at least one planar carrier region, also referred to as a “die pad” or “chip island”, and also a plurality of contact leads, which are located at the edge region of the leadframe. The optical or electronic component is in this case respectively arranged on a carrier region. Instead of a leadframe, however, it is also possible in principle for any other carriers to be used, for example carriers which comprise a patterned film of plastic or a printed circuit board. It is also possible in principle to dispense with a separate carrier entirely.

The optical component is preferably an optoelectronic transmitting component or an optoelectronic receiving component, in particular a photodiode or an LED or a semiconductor laser. However, the optical component may also be, for example, a lens, an optical filter, a prism, a mirror or the like. If the component is an electronic component, it is preferably a sensor, in particular a pressure sensor or a temperature sensor.

For the partial removal of the polymer compound, a milling device or a laser ablation device is used for example. In this case, the actual construction of the device is immaterial. The device must merely permit a defined partial removal of the polymer material.

The step of encapsulating with polymer compound preferably comprises embedding or press-molding the component with the polymer compound. The embedding or press-molding may in this case take place in a special mold, in particular an injection mold.

### BRIEF DESCRIPTION OF THE DRAWINGS

The invention is explained in more detail below on the basis of an exemplary embodiment with reference to the figures, in which:

FIG. 1 shows a sectional view of an optical module with an optical component during the production of the module and after embedding of the module with a polymer compound;

FIG. 2 shows the finished optical module, produced by the method of the present invention;

FIG. 3 shows in a frontal view the module with an opening introduced into the plastic package, exposing an optical component, and also a three-point anchorage for the coupling of an optical plug to the module, the three-point anchorage being aligned with respect to the optical component;

FIG. 4A shows a module provided with an opening exposing an optical component, two venting ducts being formed in the plastic compound of the module laterally of the opening;

FIG. 4B shows a schematic plan view of the opening and the venting ducts of FIG. 3A;

FIG. 4C shows a sectional view of the module of FIG. 3A in the region of the opening and the venting ducts;

FIG. 5 shows a sectional representation of any optical module provided with an opening, which module has lasered blind holes for the coupling of a likewise represented optical element;

FIG. 6 shows a sectional representation of an optical module provided with an opening, to which module a schematically represented optical element is coupled;

FIG. 7 shows an exemplary embodiment of an optoelectronic module in which the projecting connecting piece, which provides interface for the coupling of a fiber plug, is provided as the functional structure introduced into the plastic package;

FIG. 8 shows a fiber plug which is suitable for the coupling with the optoelectronic module of FIG. 7.

### DESCRIPTION OF A PREFERRED EXEMPLARY EMBODIMENT

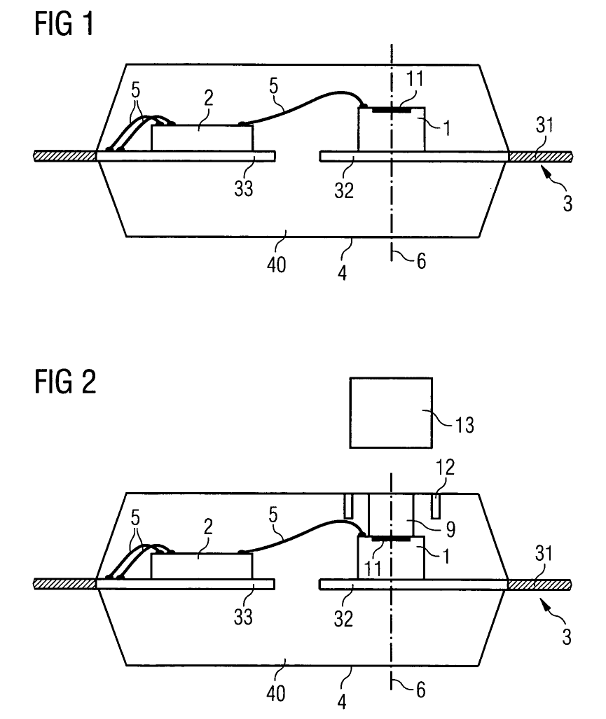

FIG. 1 shows an optical module with an optical component 1 and an assigned electronic device 2, which are arranged on a leadframe 3 and embedded with a non-transparent polymer compound 40, which provides a plastic package 4.

The optical component 1 is, for example, a luminescence diode (LED), a semiconductor laser or a photodiode. The electronic device 2 is, for example, a driver or a preamplifier. The optical component 2 preferably takes the form of a prefabricated chip. The electronic device 2 preferably takes the form of an integrated circuit (IC).

The leadframe 3 has two planar carrier areas 32, 33, which are also referred to as “die pads” and on which on the one hand the optical component 1 and on the other hand the electronic device 2 are arranged. Furthermore, the leadframe 3 has at its edge a plurality of contact leads. In this case, the contact leads project from the embedding compound 4. Leadframes 3 of this type are known in the prior art, so are not discussed any further.

Arranged on the two carrier areas 32, 33 are the optical component 1 and the electronic device 2. Electrical contacting of these module components 1, 2 takes place on the one hand by a contact on the underside, which is electrically connected directly to the respective carrier area 32, 33, and on the other hand by means of bonding wires 5.

The optical component 1 has on its upper side an operative region 11. This is, for example, a light-emitting area 11 of an LED chip.

To provide a favorable coefficient of thermal expansion, the polymer compound 40 is provided with a filler and is therefore not transparent for the light emitted or received. The optical path of the optical component 1 is closed.

It is therefore envisaged to introduce an opening 9 into the polymer compound 40 in a further method step, so that the operative region 11 of the optical component 1 is exposed and the optical component 1 can enter into operative connection with the surroundings. The correspondingly completed module is represented in FIG. 2.

For the formation of an opening 9 in the polymer compound 40, it is envisaged to use a laser ablation device 13, which is represented in FIG. 2 as a functional block. In a configuration given by way of example, the laser ablation device 13 comprises a laser, for example an Nd:YAG laser, which emits light of a wavelength of 1064 nm, and also a mirror drum assigned to the laser. The laser is in this case arranged in such a way that the beam emitted by the laser falls on the rotating mirror drum. The mirror drum has a polygonal cross section, so that, when the mirror drum rotates about a horizontal longitudinal axis, the laser beam is deflected in a limited laser beam region, the opening 9 being formed in the non-transparent polymer compound 40. Suitable mirror surfaces of the mirror drum achieve the effect that the laser beam extends over a surface area on the polymer compound, so that a three-dimensional laser-ablated opening is dug into the plastic package 4.

Depending on the exact configuration of the laser ablation device, the opening 9 may in this case have different configurations. Generally, the laser-ablated opening 9, which is merely schematically represented in FIG. 2, will be formed in a funnel-shaped manner.

The formation of an opening 9 in the plastic package using a laser ablation device has the advantage that an opening can be introduced into the polymer compound 40 with high precision.

Also formed in the plastic package 4 is a functional structure 12, which is introduced into the polymer compound 40 by the laser ablation device 13 (or alternatively by a suitable milling device). In FIG. 2, the functional structure 12 is merely schematically represented and by way of example in the form of bores 12. The bores 12 are aligned with respect to the optical component 1 and, in the exemplary embodiment represented, serve for the passive adjustment and attachment of an optical plug (not represented) to the module.

In this case, it is preferably provided that the exact position of the component 1 and its operative area 11 is determined after the opening of the package by the laser ablation device 13. An adjustment and attachment structure (in the form of the bores 12 or in some other way) can then be introduced into the plastic package 4 by means of the laser ablation device 13 exactly in relation to this determined position, so that an exact alignment of an optical fiber or some other optical element with respect to the component 1 and its operative area 11 can also take place by means of a passive adjustment. The method is in this case very effective, since the functional structures 12 are introduced into the plastic package 4 directly by the device 13, which also provides the opening 9.

The method described permits a passive adjustment of an element to be coupled to the module and consequently avoids a complex active adjustment.

Alternatively, it may also be provided that the exact position of the component 1 is recorded directly after the provision of the component 1 on the leadframe 3 (that is before the embedding with the polymer compound 40) and that this position is then documented. Depending on the placement accuracy of the “die bonder” used in this case, here too the provision of functional structures on the module package 4 takes place in a defined position. It is also conceivable in principle that the position of the optical component is determined with respect to reference surfaces of the leadframe 3. However, a prerequisite here is that the placement accuracy of the component 1 with respect to the leadframe 3 is sufficiently accurate and to ensure that a passive adjustment can still take place with sufficient coupling accuracy with functional structures which are aligned in this way it in relation to the component 1.

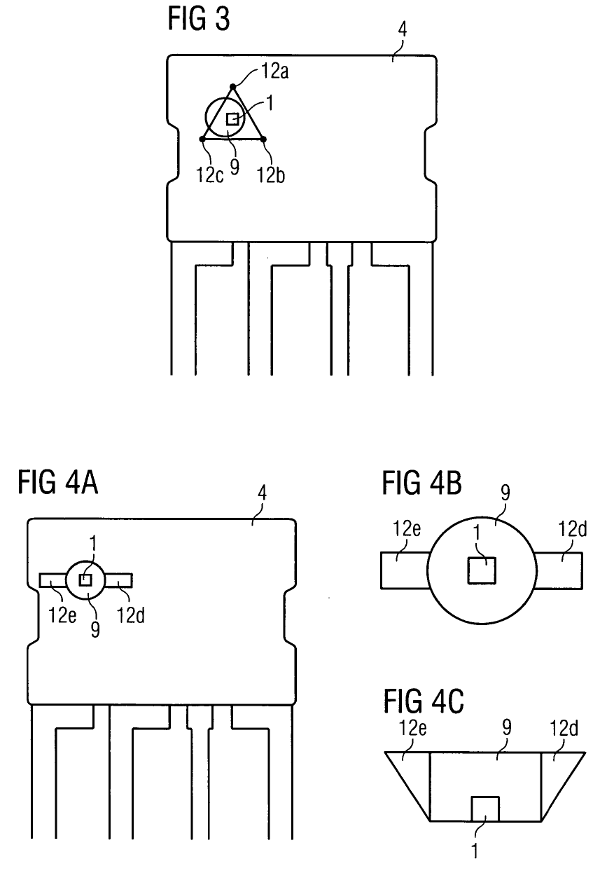

FIG. 3 shows an actual exemplary embodiment in which the opening 9 has been cut out by a laser in the polymer compound 40 of the plastic package 4 of the module. Exposed by the opening 9 is an optoelectronic component 1, which however is not arranged centrally in the opening in the exemplary embodiment represented, for instance on account of positional tolerances of the component 1 with respect to the leadframe 3. The actual position of the component 1 is then determined, for instance by means of an image processing system, and a functional structure in the form of a three-point anchorage (comprising three bores 12a, 12b, 12c) is then introduced into the polymer compound 40 with respect to this actual position. An optical plug, which is coupled to the module by means of the three-point anchorage, is then positioned exactly with respect to the one component 1, without any need for an active adjustment.

FIGS. 4A to 4C show an exemplary embodiment in which the functional structure which is introduced into the plastic package 4 forms two venting ducts 12d, 12e, which extend laterally of the opening 9 and, adjacent the latter, into the interior of the module from the surface of the package. As the sectional view of FIG. 4C reveals, the venting ducts 12d, 12e in this case taper in the direction of the component 1. Unlike in the case of the previous exemplary embodiment of FIG. 3, the ventilating ducts 12d, 12e in this case are not aligned with respect to the component 1, but with respect to the opening 9 introduced into the module, since they are intended to be directly adjacent it. They serve the purpose of ensuring when a transparent polymer compound is introduced into the opening 9 that, as filling with the transparent polymer compound proceeds, air can escape at the sides and consequently no air bubbles are trapped. Consequently, a kind of air-ducting channels are introduced into the plastic package 4 as a functional structure by means of the structuring laser ablation device 13.

FIG. 5 shows an exemplary embodiment in which an optical element 14 with an integrated lens 15 is introduced by means of projecting guiding pins 141 into lasered blind holes 12f, 12g of the module package. The opening 9 cut out by laser is in this case filled with a transparent polymer 16. The blind holes 12f, 12g are preferably aligned in the direction of the optical component 1.

Also provided as an additional functional area is a shallow recess 17 on the surface of the plastic package 4, which extends adjacent the opening 9 and serves as an equalizing reservoir for the transparent polymer compound 16. When the optical element 14 is placed onto the module, excess transparent polymer compound 16 can escape into this equalizing reservoir 17. Furthermore, on account of the equalizing reservoir 17, in the case of thermal expansion, the transparent polymer compound (for example silicone) has adequate space to expand, without exerting a strong mechanical loading on the component.

In the exemplary embodiment of FIG. 5, the optical element is a planar window 14 with an integrated lens 15. However, it is similarly conceivable to connect plane-parallel plates, which act for example as block filters, or else deflecting devices, beam splitters etc. to the module by means of the functional structures 12f, 12g.

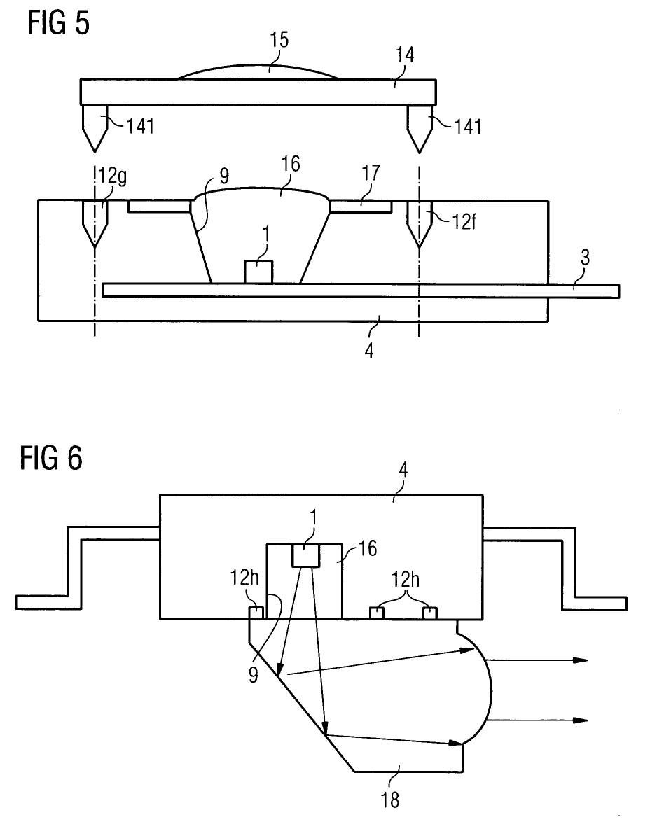

FIG. 6 shows an exemplary embodiment in this respect, in which the optical component 1 is cut out by laser in a way similar to the exemplary embodiment of FIG. 5 and the opening 9 thereby created is filled with a transparent polymer material 16. A deflecting device 18 with an integrated lens is attached to the module by means of schematically represented latching elements 12h. A preferred possible application for this configuration is the coupling of light into optical printed circuit boards.

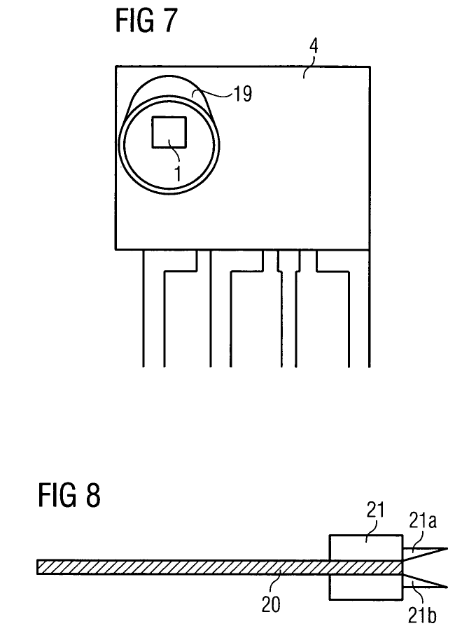

FIG. 7 shows a type of module that has a projecting package connecting piece 19 as a functional structure. This is a so-called CAI (cavity as interface) module. The projecting connecting piece 19 serves for guiding fibers and coupling an optical plug. The corresponding optical plug is represented by way of example gin FIG. 8. The optical waveguide 20 is secured at its end in a holder 21 (also referred to as an insert) with two protruding lugs 21a, 21b. The insert 21 is inserted by the lugs 21a, 21b into the CAI module, to be precise into the coupling connecting piece 19. The connection may take place for example by means of a bayonet fastener.

When providing a package connecting piece 19 on the package, it is necessary to remove a relatively large volume of polymer compound. Alternatively, it may be provided that the connecting piece 19 is produced separately and is positioned on the package by means of adjustment structures provided on the optical component.

It is pointed out that the component 1 may also be an electronic component. For example, the component 1 may be a sensor chip, in particular a pressure sensor or a temperature sensor, as are used in the automobile industry.

Furthermore, it is pointed out that the module may have a number of optical or electronic components of the type described, openings and functional structures then being introduced into the module package for at least one of the components.

The production of the optical or electronic module preferably takes place as repeats on a multi-cavity mold, the individual optical or electronic modules being singulated after curing of the polymer material and exposure of the respective components and provision of the functional structures.
We claim:

1. A method for producing an optical or electronic module provided with a plastic package, the method comprising:
providing at least one optical or electronic component, the component having an operative region, via which it is in operative connection with the surroundings in the finished module,
encapsulating the at least one component with at least one polymer compound to form the plastic package,
partially removing the polymer compound from the outside by a device for the partial removal of the polymer compound in such a way that the polymer compound between the operative region of the component and the outer side of the plastic package is at least partially removed, and
introducting a functional structure into the remaining polymer compound by means of the device.

2. The method as claimed in claim 1, which further comprises, before or after the partial removal of the polymer compound, recording the position of the component by direct or indirect measurement, and inscribing the functional structure in the polymer compound in a defined position in relation to the recorded position of the component.

3. The method as claimed in claim 1, which further comprises inscribing the functional structure in the polymer compound in a defined position in relation to an opening which is created when the polymer compound in the plastic package is partially removed.

4. The method as claimed in claim 1, wherein the functional structure comprises at least one adjustment structure, which permits a passive adjustment of an element to be coupled to the module with respect to the component.

5. The method as claimed in claim 4, wherein the adjustment structure comprises at least one adjustment mark, which is inscribed in the surface of the plastic package

6. The method as claimed in claim 4, wherein the adjustment structure serves not only for adjustment but also for attachment of the element to be coupled.

7. The method as claimed in claim 6, wherein the adjustment structure comprises attachment structures, which permit attachment of an element to be coupled in a defined position on the plastic package (4).

8. The method as claimed in claim 7, wherein at least one bore is inscribed in the plastic package as an attachment structure.

9. The method as claimed in claim 7, wherein a package connecting piece which serves for the direct coupling of an optical plug is inscribed in the plastic package as the attachment structure.

10. The method as claimed in claim 1, wherein the opening which is created when the polymer compound in the plastic package is partially removed is filled with a transparent embedding material after the exposure of the component.

11. The method as claimed in claim 10, wherein the functional structure has at least one ventilating duct, which extends from the surface of the plastic package into the interior of the plastic package adjacent the opening in the plastic package.

12. The method as claimed in claim 10, wherein a shallow recess, which forms an equalizing reservoir for the transparent embedding material, is formed laterally of the opening in the surface of the plastic package as a functional structure or part of the functional structure.

13. The method as claimed in claim 1, wherein the optical or electronic component is arranged on a carrier before the encapsulation.

14. The method as claimed in claim 13, wherein the carrier takes the form of a leadframe, which has on the one hand at least one planar carrier region and on the other hand a plurality of contact leads, which are located at the edge region of the leadframe, and the optical or electronic component being respectively arranged on a carrier region.

15. The method as claimed in claim 1, wherein the optical component is an optoelectronic transmitting component or an optoelectronic receiving component.

16. The method as claimed in claim 1, wherein a laser ablation device is used for the partial removal of the polymer compound.

17. The method as claimed in claim 1, wherein a milling device is used for the partial removal of the polymer compound.

18. A method for producing a module including at a component housed in a plastic package, said component comprising at least one of an optical component and an electronic component, the method comprising:
encapsulating said at least one component in a polymer compound such that the polymer compound forms at least a portion of the plastic package;
utilizing a single tool to remove portions of the polymer compound such that the plastic package defines both an opening that exposes the component and one or more functional holes; and
mounting a functional structure into at least one of the opening and said one or more functional holes.

19. The method according to claim 18, wherein said single tool comprises a laser, and wherein forming the opening and said one or more functional holes comprises controlling the laser to ablate said portions of the polymer compound.
